(19) United States
(12) Patent Application Publication
(10) Pub. No.: US 2024/0291440 A1
(43) Pub. Date: Aug. 29, 2024

(54) TUNABLE HIGH-LINEARITY LOW NOISE AMPLIFIER

(71) Applicant: Apple Inc., Cupertino, CA (US)

(72) Inventors: Julian W. Zuber, Erlangen (DE); Christian F. Tanzer, Perlesreut (DE); Dominic Koehler, Viereth-Trunstadt (DE)

(21) Appl. No.: 18/441,744

(22) Filed: Feb. 14, 2024

Related U.S. Application Data
(60) Provisional application No. 63/448,535, filed on Feb. 27, 2023.

(51) Int. Cl. H03F 1/32; H03F 3/193

(52) U.S. Cl. CPC H03F 1/3205; H03F 3/193; H03F 2200/294

(57) ABSTRACT

An amplifier (e.g., a low noise amplifier (LNA)) may operate in multiple modes, including a first, default mode (e.g., a high gain and/or power-saving mode) which may apply when an out-of-band blocker signal (e.g., transmitted or received by other radios, transceivers, or devices) is not present. The LNA may also operate in a second, Long Term Evolution (LTE) blocking or high linearity mode, which may be selected when a blocker and/or transmission signal leakage is present during, for example, LTE operation. The LNA may further operate in a third, Global System for Mobile (GSM) blocking mode, which may include a high compression point to withstand a GSM blocker that may be present during, for example, GSM operation. The LNA may also operate in a protection mode when voltage of a received signal is excessive to protect the LNA or device having the LNA.

### CROSS-REFERENCE TO RELATED APPLICATIONS

This application claims the benefit of U.S. Provisional Application No. 63/448,535, filed Feb. 27, 2023, entitled “Tunable High-Linearity Low Noise Amplifier,” which is incorporated by reference herein in its entirety for all purposes.

### BACKGROUND

The present disclosure relates generally to wireless communication, and more specifically to isolating wireless signals between transmitters and receivers in wireless communication devices.

In an electronic device, a transmitter and a receiver may each be coupled to one or more antennas to enable the electronic device to both transmit and receive wireless signals. The electronic device may include an electrical balanced duplexer (EBD) that isolates the transmitter from received signals of a first frequency range, and isolates the receiver from transmission signals of a second frequency range (e.g., thus implementing frequency division duplex (FDD) operations). In this manner, interference between the transmission and received signals may be reduced when communicating using the electronic device. However, the EBD may not sufficiently block out-of-band and/or transmission signals, which may result in the out-of-band and/or transmission signals affecting receiver sensitivity and/or the received signals.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, an amplifier comprises a first transistor, an inductor and a capacitor coupled in parallel and coupled to a terminal of the first transistor, a second transistor coupled to the terminal of the first transistor, the inductor, and the capacitor, and a third transistor coupled to the terminal of the first transistor, the inductor, and the capacitor. The amplifier also comprises switching circuitry coupled to the second transistor and the third transistor.

In another embodiment, an electronic device comprises an amplifier configured to operate in a plurality of modes and a blocker detection circuit coupled to the amplifier configured to detect a presence of a blocking signal. The electronic device also comprises a switch coupled to the amplifier and configured to select a mode of the plurality of modes based on the presence of the blocking signal.

In yet another embodiment, a method comprises operating, via processing circuitry, an amplifier in a first mode based on a voltage of a received signal being greater than a threshold voltage, the first mode configured to protect the amplifier from the voltage. The method also comprises operating, via the processing circuitry, the amplifier in a second mode based on a signal blocker not being present, and operating, via the processing circuitry, the amplifier in a third mode based on the signal blocker being present and the received signal corresponding to a first radio access technology. The method further comprises operating, via the processing circuitry, the amplifier in a fourth mode based on the signal blocker being present and the received signal corresponding to a second radio access technology.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a functional diagram of the electronic device of FIG. 1, according to embodiments of the present disclosure;

FIG. 3 is a block diagram of a transceiver of the electronic device of FIG. 1, according to embodiments of the present disclosure;

FIG. 4 is a schematic diagram of a transmitter of the electronic device of FIG. 1, according to embodiments of the present disclosure;

FIG. 5 is a schematic diagram of a receiver of the electronic device of FIG. 1, according to embodiments of the present disclosure;

FIG. 6 is a schematic diagram of operating modes of a low noise amplifier (LNA) of the electronic device of FIG. 1, according to embodiments of the present disclosure;

FIG. 7 is a block diagram of operating mode circuitry of the LNA of the electronic device of FIG. 1, according to embodiments of the present disclosure;

FIG. 8 is a circuit diagram of the LNA of the electronic device of FIG. 1, according to embodiments of the present disclosure;

FIG. 9 is a circuit diagram of the LNA of FIG. 8 showing components of tunable capacitors, according to embodiments of the present disclosure;

FIG. 10 is the circuit diagram of the LNA of FIG. 8 when operating in a first, high gain and/or power-saving mode, according to embodiments of the present disclosure;

FIG. 11 is the circuit diagram of the LNA of FIG. 8 when operating in the second, high linearity, Long Term Evolution (LTE) blocking mode, according to embodiments of the present disclosure;

FIG. 12 is the circuit diagram of the LNA of FIG. 8 when operating in a third, Global System for Mobile (GSM) blocking mode, according to embodiments of the present disclosure; and

FIG. 13 is the circuit diagram of the LNA of FIG. 8 when operating in an LNA or device protection mode, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

This disclosure is directed to isolating wireless signals between transmitters and receivers in wireless communication devices. In an electronic device, a transmitter and a receiver may each be coupled to one or more antennas to enable the electronic device to both transmit and receive wireless signals. In some devices, one or more surface acoustic wave (SAW) filters may be used to filter the transmitter from received signals of a first frequency range, and filter the receiver from transmission signals of a second frequency range. However, SAW filters may take excessive space in the electronic device to implement, particularly when multiple SAW filters are implemented to address multiple frequency ranges, and result in unacceptable gain losses.

In other devices, a SAW-less duplexer system, such as an electrical balanced duplexer (EBD), may be used to isolate the transmitter from received signals of a first frequency range, and isolate the receiver from transmission signals of a second frequency range (e.g., thus implementing frequency division duplex (FDD) operations). Such systems may further be tunable to accommodate for different transmission and receive frequency ranges, thus saving space when compared to using multiple SAW filters. In this manner, interference between the transmission and received signals may be reduced when communicating using the electronic device, while reducing sizes of the devices. However, for Long Term Evolution (LTE) cellular signals, the out-of-band (OOB) (e.g., blocker) signals (e.g., transmitted or received by other radios, transceivers, or devices) and/or transmission signals (e.g., transmitted by the transmitter of the electronic device) may mix, resulting in intermodulation products (e.g., second order intermodulation products (IM2) or third order intermodulation products (IM3)) that may affect sensitivity of the receiver and/or received signals. Moreover, for Global System for Mobile (GSM) cellular signals, compression and noise figure desensitization may occur at the receiver and/or in received signals due to poor or insufficient OOB filtering characteristics by the EBD, which may overdrive a low-noise amplifier (LNA) of the receiver.

Accordingly, embodiments herein provide an amplifier (e.g., a low noise amplifier (LNA)) that provides highly linear performance with a high compression point in GSM operation and high OOB rejection (e.g., of a third order intercept point (IIP3)) in LTE operation. Compression point may refer to when an amplifier's behavior compresses from linear to sufficiently non-linear. Thus, the higher the compression point, the better performance provided by the amplifier. As such, the disclosed embodiments include an LNA that is capable of performing both GSM and LTE operations (e.g., amplifying signals having frequencies in either GSM or LTE frequency bands, such as between 600 megahertz. (MHz) and 1 gigahertz. (GHz)). The LNA may include a narrowband architecture to reduce noise, as wideband architectures are susceptible to more noise. As such, the LNA may be tunable in frequency to operate in multiple modes (e.g., for different, narrow frequency bands), and be referred as a multi-mode multi-band LNA. In particular, the multiple modes may include a first, default mode (e.g., a high gain and/or power-saving mode) which may be selected when a blocker is not present. The first mode may result in the LNA performing with high gain, low noise, low current (e.g., similar to an LNA in a SAW-based system). Linearity may not be crucial here due to no blocker being present. The LNA may also perform in a second, LTE blocking or high linearity mode, which may be selected when an OOB blocker and/or transmission signal leakage is present during, for example, LTE operation. Due to the OOB blocker and/or the transmission signal leakage, the second mode may include high OOB and/or IM3 blocking or prevention to reduce intermodulations. The second mode may also result in the LNA performing with low noise. Because the second mode includes IM3 blocking or cancelation along with linearization, it may also result in a drop in gain and/or an increase in current consumption. The LNA may further perform in a third, GSM blocking mode, which may include a high compression point to withstand a 0 decibel (dB) GSM blocker that may be present during, for example, GSM operation. It should be understood that, while the disclosed LNA is described as operating in three modes, one specific to LTE operation and one specific to GSM operation. LTE and GSM are used as example radio access technologies (RATs), and in additional or alternative embodiments, other RATs may be substituted (e.g., New Radio (NR), Bluetooth®, Wi-Fi, Universal Mobile Telecommunications System (UMTS), and so on).

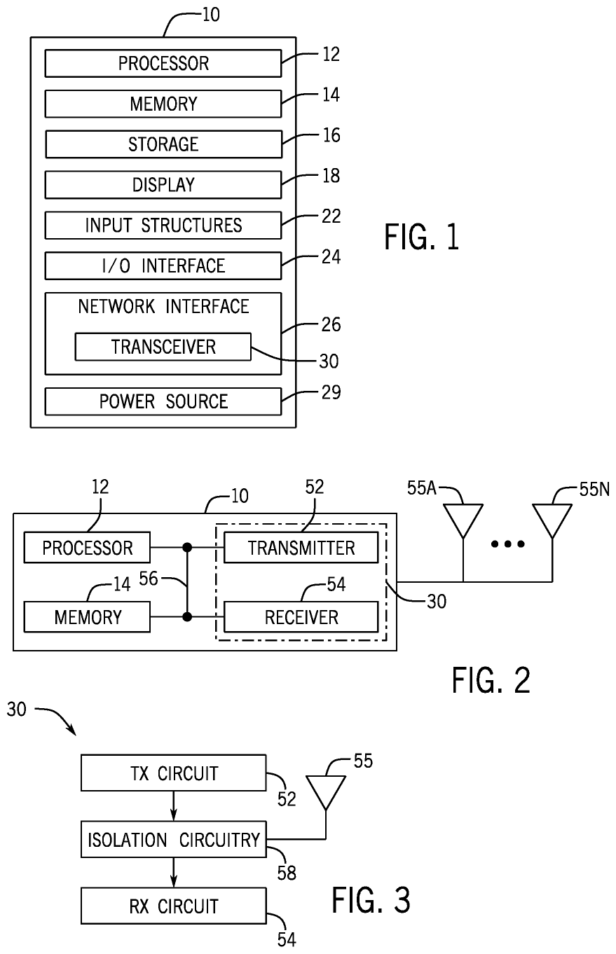

FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. It should be noted that FIG. 1 is merely one example of a particular implementation and is intended to illustrate the types of components that may be present in the electronic device 10.

By way of example, the electronic device 10 may include any suitable computing device, including a desktop or notebook computer (e.g., in the form of a MacBook®, MacBook® Pro, MacBook Air®, iMac®, Mac® mini, or Mac Pro® available from Apple Inc. of Cupertino, California), a portable electronic or handheld electronic device such as a wireless electronic device or smartphone (e.g., in the form of a model of an iPhone® available from Apple Inc. of Cupertino, California), a tablet (e.g., in the form of a model of an iPad® available from Apple Inc. of Cupertino, California), a wearable electronic device (e.g., in the form of an Apple Watch® by Apple Inc. of Cupertino, California), and other similar devices. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector provided by Apple Inc. of Cupertino, California, a universal serial bus (USB), or other similar connector and protocol. The network interface 26 may include, for example, one or more interfaces for a personal area network (PAN), such as an ultra-wideband (UWB) or a BLUETOOTH® network, a local area network (LAN) or wireless local area network (WLAN), such as a network employing one of the IEEE 802.11x family of protocols (e.g., WI-FI®), and/or a wide area network (WAN), such as any standards related to the Third Generation Partnership Project (3GPP), including, for example, a 3^{rd} generation (3G) cellular network, Global System for Mobile (GSM) cellular network, universal mobile telecommunication system (UMTS), 4th generation (4G) cellular network, Long Term Evolution (LTE®) cellular network, Long Term Evolution License Assisted Access (LTE-LAA) cellular network, 5^{th} generation (5G) cellular network, and/or New Radio (NR) cellular network, a 6th generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX®), mobile broadband Wireless networks (mobile WIMAX®), asynchronous digital subscriber lines (e.g., ADSL, VDSL), digital video broadcasting-terrestrial (DVB-T®) network and its extension DVB Handheld (DVB-H®) network, ultra-wideband (UWB) network, alternating current (AC) power lines, and so forth.

As illustrated, the network interface 26 may include a transceiver 30. In some embodiments, all or portions of the transceiver 30 may be disposed within the processor 12. The transceiver 30 may support transmission and receipt of various wireless signals via one or more antennas, and thus may include a transmitter and a receiver. In particular, the transceiver 30 may include an amplifier (e.g., a low noise amplifier (LNA)) that operates in multiple modes, including a first, default mode (e.g., a high gain and/or power-saving mode) which may apply when an out-of-band blocker signal (e.g., transmitted or received by other radios, transceivers, or devices) is not present. The LNA may also operate in a second, Long Term Evolution (LTE) blocking or high linearity mode, which may be selected when a blocker and/or transmission signal leakage is present during, for example, LTE operation. The LNA may further operate in a third, Global System for Mobile (GSM) blocking mode, which may include a high compression point to withstand a GSM blocker that may be present during, for example, GSM operation. The LNA may also operate in a protection mode when voltage of a received signal is excessive to protect the LNA or device having the LNA. The power source 29 of the electronic device 10 may include any suitable source of power, such as a rechargeable lithium polymer (Li-poly) battery and/or an alternating current (AC) power converter.

FIG. 2 is a functional diagram of the electronic device 10 of FIG. 1, according to embodiments of the present disclosure. As illustrated, the processor 12, the memory 14, the transceiver 30, a transmitter 52, a receiver 54, and/or antennas 55 (illustrated as 55A-55N, collectively referred to as an antenna 55) may be communicatively coupled directly or indirectly (e.g., through or via another component, a communication bus, a network) to one another to transmit and/or receive signals between one another.

The electronic device 10 may include the transmitter 52 and/or the receiver 54 that respectively enable transmission and reception of signals between the electronic device 10 and an external device via, for example, a network (e.g., including base stations or access points) or a direct connection. As illustrated, the transmitter 52 and the receiver 54 may be combined into the transceiver 30. The electronic device 10 may also have one or more antennas 55A-55N electrically coupled to the transceiver 30. The antennas 55A-55N may be configured in an omnidirectional or directional configuration, in a single-beam, dual-beam, or multi-beam arrangement, and so on. Each antenna 55 may be associated with one or more beams and various configurations. In some embodiments, multiple antennas of the antennas 55A-55N of an antenna group or module may be communicatively coupled to a respective transceiver 30 and each emit radio frequency signals that may constructively and/or destructively combine to form a beam. The electronic device 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

As illustrated, the various components of the electronic device 10 may be coupled together by a bus system 56. The bus system 56 may include a data bus, for example, as well as a power bus, a control signal bus, and a status signal bus, in addition to the data bus. The components of the electronic device 10 may be coupled together or accept or provide inputs to each other using some other mechanism.

FIG. 3 is a block diagram of the transceiver 30 (e.g., transceiver circuitry) of the electronic device 10, according to embodiments of the present disclosure. As illustrated, the transceiver circuitry 30 includes an isolation circuit 58 disposed between a transmitter (e.g., a transmit circuit 52) and a receiver (e.g., a receive circuit 54). The isolation circuit 58 is communicatively coupled to the transmitter 52 and the receiver 54, and may include any suitable circuitry that enables isolating the transmitter 52 from the receiver 54, and vice versa, such as a duplexer, an electrical balanced duplexer (EBD), a phase balance duplexer, a double balanced duplexer, a circular balanced duplexer, and so on. In some embodiments, the isolation circuit 58 is coupled to one or more antennas 55. In some alternative embodiments, the one or more antennas 55 may be disposed within the isolation circuit 58. The isolation circuit 58 enables signals (e.g., transmission signals) of a first frequency range from the transmitter 52 to pass through to the one or more antennas 55 and blocks the signals of the first frequency range from passing through to the receiver 54. The isolation circuit 58 also enables signals (e.g., received signals) of a second frequency range received via the one or more antennas 55 to pass through to the receiver 54 and blocks the received signals of the second frequency range from passing through to the transmitter 52. Each frequency range may be of any suitable bandwidth, such as between 0 and 100 gigahertz (GHz) (e.g., 10 megahertz (MHz)), and include any suitable frequencies. For example, the first frequency range (e.g., a transmit frequency range) may be between 880 and 890 MHz, and the second frequency range (e.g., a receive frequency range) may be between 925 and 936 MHz.

In some embodiments, the isolation circuit 58 isolates the receiver 54 from a transmission signal generated by the transmitter 52. For example, when transmitting a transmit signal, some of the transmit signal (e.g., a transmit leakage signal) may propagate toward the receiver 54. If a frequency of the transmit leakage signal is within the receive frequency range (e.g., is a frequency supported by the receiver 54), the transmit leakage signal may interfere with a receive signal and/or the receiver 54. To prevent such interference, the isolation circuit 58 may isolate the receiver 54 from the transmit leakage signal.

In additional or alternative embodiments, the isolation circuit 58 isolates the transmitter 52 from a received signal received via the one or more antennas 55. For example, when receiving a received signal from the one or more antennas 55, some of the received signal (e.g., a receive leakage signal) may propagate toward the transmitter 52. If a frequency of the receive leakage signal is within the transmit frequency range (e.g., is a frequency supported by the transmitter 52), the receive leakage signal may interfere with the transmit signal and/or the transmitter 52. To prevent such interference, the isolation circuit 58 may isolate the transmitter 52 from the receive leakage signal.

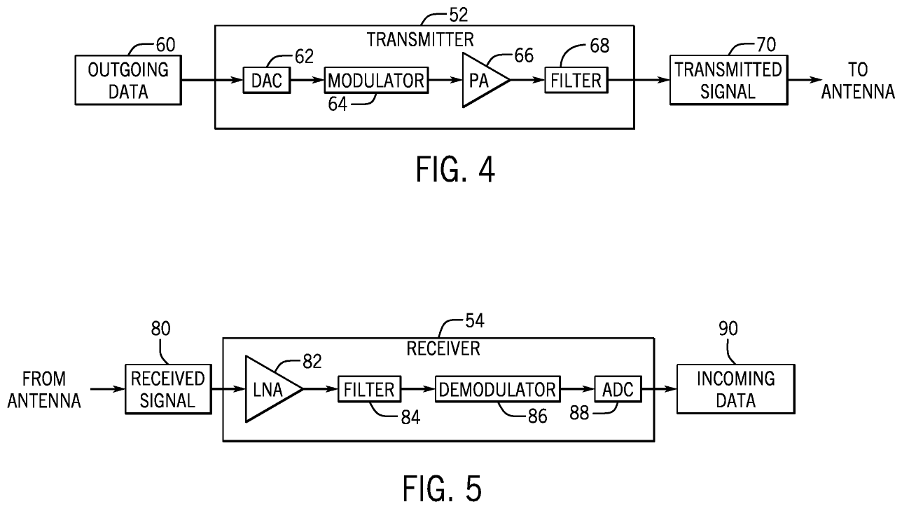

FIG. 4 is a schematic diagram of the transmitter 52 (e.g., transmit circuitry), according to embodiments of the present disclosure. As illustrated, the transmitter 52 may receive outgoing data 60 in the form of a digital signal to be transmitted via the one or more antennas 55. A digital-to-analog converter (DAC) 62 of the transmitter 52 may convert the digital signal to an analog signal, and a modulator 64 may combine the converted analog signal with a carrier signal to generate a radio wave. A power amplifier (PA) 66 receives the modulated signal from the modulator 64. The power amplifier 66 may amplify the modulated signal to a suitable level to drive transmission of the signal via the one or more antennas 55. A filter 68 (e.g., filter circuitry and/or software) of the transmitter 52 may then remove undesirable noise from the amplified signal to generate transmitted signal 70 to be transmitted via the one or more antennas 55. The filter 68 may include any suitable filter or filters to remove the undesirable noise from the amplified signal, such as a bandpass filter, a bandstop filter, a low pass filter, a high pass filter, and/or a decimation filter.

The power amplifier 66 and/or the filter 68 may be referred to as part of a radio frequency front end (RFFE), and more specifically, a transmit front end (TXFE) of the electronic device 10. Additionally, the transmitter 52 may include any suitable additional components not shown, or may not include certain of the illustrated components, such that the transmitter 52 may transmit the outgoing data 60 via the one or more antennas 55. For example, the transmitter 52 may include a mixer and/or a digital up converter. As another example, the transmitter 52 may not include the filter 68 if the power amplifier 66 outputs the amplified signal in or approximately in a desired frequency range (such that filtering of the amplified signal may be unnecessary).

FIG. 5 is a schematic diagram of the receiver 54 (e.g., receive circuitry), according to embodiments of the present disclosure. As illustrated, the receiver 54 may receive received signal 80 from the one or more antennas 55 in the form of an analog signal. A low noise amplifier (LNA) 82 may amplify the received analog signal to a suitable level for the receiver 54 to process. A filter 84 (e.g., filter circuitry and/or software) may remove undesired noise from the received signal, such as cross-channel interference. The filter 84 may also remove additional signals received by the one or more antennas 55 that are at frequencies other than the desired signal. The filter 84 may include any suitable filter or filters to remove the undesired noise or signals from the received signal, such as a bandpass filter, a bandstop filter, a low pass filter, a high pass filter, and/or a decimation filter. The low noise amplifier 82 and/or the filter 84 may be referred to as part of the RFFE, and more specifically, a receiver front end (RXFE) of the electronic device 10.

A demodulator 86 may remove a radio frequency envelope and/or extract a demodulated signal from the filtered signal for processing. An analog-to-digital converter (ADC) 88 may receive the demodulated analog signal and convert the signal to a digital signal of incoming data 90 to be further processed by the electronic device 10. Additionally, the receiver 54 may include any suitable additional components not shown, or may not include certain of the illustrated components, such that the receiver 54 may receive the received signal 80 via the one or more antennas 55. For example, the receiver 54 may include a mixer and/or a digital down converter.

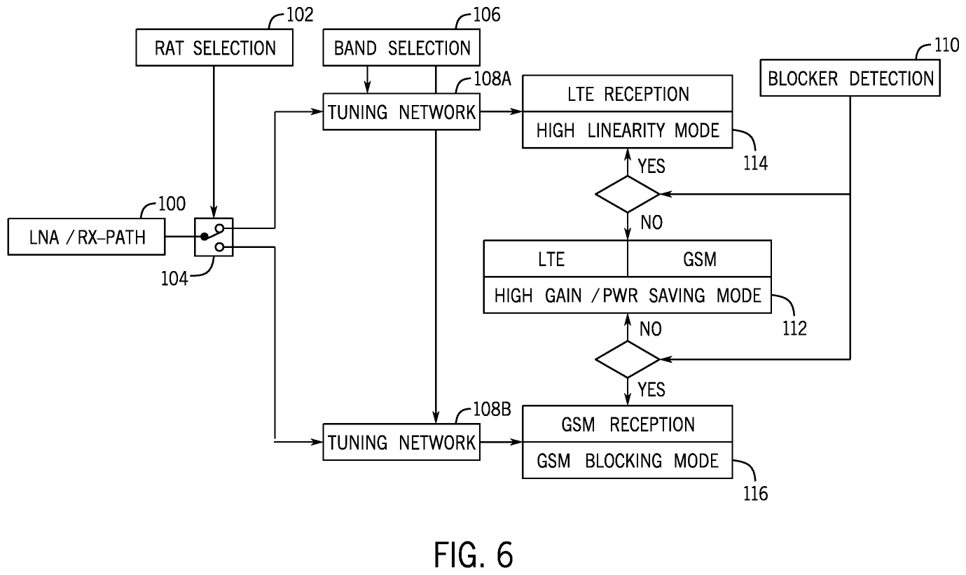

FIG. 6 is schematic diagram of operating modes of the LNA 82, according to embodiments of the present disclosure. On an LNA/receiver (RX) path 100 that couples to the LNA 82 and/or receiver 54, the processor 12 receives an indication of or determines a radio access technology (RAT) 102 with which to communicate, such as LTE or GSM, and selects the RAT 102 via a switch 104. The processor 12 receives an indication of or determines a frequency band 106 with which to communicate (e.g., used by the RAT 102), and adjusts a corresponding tuning network 108A, 108B (collectively 108) based on the frequency band. The tuning network 108 may adjust or tune components of the LNA 82 to communicate using the frequency band. In particular, the processor 12 may adjust the tuning network 108A for the frequency band 106 if LTE is the RAT 102, and adjust the tuning network 108B for the frequency band 106 if GSM is the RAT 102. It should be understood that any switch (e.g., 104) or transistor discussed in this disclosure may include any suitable switching circuitry.

The processor 12 may also receive an indication of or determine whether a blocker 110 is present. If not, and the RAT 102 is LTE, then the processor 12 operates the LNA 82 in a first, default, high gain and/or power-saving mode 112 for LTE. If the blocker 110 is not present, and the RAT 102 is GSM, then the processor 12 operates the LNA 82 in the first mode 112 for GSM. On the other hand, if the blocker 110 is present, and the RAT 102 is LTE, then the processor 12 operates the LNA 82 in a second, high linearity, LTE blocking mode 114. If the blocker 110 is present, and the RAT 102 is GSM, then the processor 12 operates the LNA 82 in a third, GSM blocking mode 116.

In the first, high gain and/or power-saving mode 112, the LNA 82 may consume low current, provide high gain, and/or exhibit low noise, as the LNA 82 may not prioritize linearity since there are no blockers present. That is, because there are no blockers present, there may be no requirements that apply to linearity of the LNA 82 (e.g., as set forth by a standards body, such as the 3GPP). In the second, high linearity, LTE blocking mode 114, there may be an applicable linearity requirement. For example, the LTE specification demands a power of OOB third order intercept point (IIP3) of a signal received by the receiver 54 according to Equation 1 below:

$$IIP {3}_{O O B} = {P}_{T X} - {ISO}_{T X - R X} + \frac{1}{2} ( {P}_{b l k} - {OOBR}_{System} - IIM 3 ) \qquad ( Equation 1 )$$

In Equation 1, P_{TX} is the power at a transmitter transmitting the received signal, ISO_{TX-RX} is isolation between the transmitter 52 and the receiver 54, P_{blk} is power of a blocking signal, OOBR_{System} is out-of-band rejection of the receiver 54, and IIM3 is power of third order intermodulation distortions (which may equal −112 decibel-milliwatts (dBm), where the LTE specification sets forth that IM3 (third order intermodulation distortions) for 8 channels is −102 dBm, one channel is approximately −109 dBm, with a 3 dB margin). Thus, in the second mode 114, the LNA 82 may consume moderate current (e.g., higher than that of the first mode 112), provide moderate gain (e.g., lower than that of the first mode 112), and/or exhibit moderate noise (e.g., higher than that of the first mode 112) to provide higher linearity when compared to the first mode 112 to meet the requirements of Equation 1.

In the third, GSM blocking mode 116, there may similarly be an applicable linearity requirement. For example, the GSM specification demands a compression point (P1_{dB}) according to Equation 2 below:

$${P}_{1 d B} = {P}_{b l k} - {OOBR}_{System} \qquad ( Equation 2 )$$

The P1_{dB} compression point may refer to when the LNA's behavior compresses from a linear behavior to 1 dB less than the (ideal) linear behavior. Thus, in the third mode 116, the LNA 82 may consume high current (e.g., higher than that of the second mode 114), provide moderate gain (e.g., lower than that of the first mode 112 and similar to that of the second mode 114), and/or exhibit low noise (e.g., similar to that of the first mode 112 and lower than that of the second mode 114) to provide higher linearity when compared to the first mode 112 to meet the requirements of Equation 2. It should be understood that, when operating in the GSM blocking mode 116, IM3 may not be a concern as the electronic device 10, the receiver 54, and/or the LNA 82 may operate according to a time-division duplexing (TDD) scheme, as set forth by the GSM specification, and, as such, intermodulation between transmission and received signals may not occur, since the signals are not transmitted and received concurrently. This may not be the case when the electronic device 10, the receiver 54, and/or the LNA 82 operates in the LTE blocking mode 114, during which the electronic device 10, the receiver 54, and/or the LNA 82 may operate according to a frequency-division duplexing (FDD) scheme, as set forth by the LTE specification, and, as such, intermodulation between transmission and received signals may occur, since the signals may be transmitted and received concurrently.

The LNA 82 may implement switchable capacitors for input and output matching. That is, the LNA 82 may be tuned (e.g., by the processor 12) for desired frequencies using the switchable capacitors, including high frequency ranges, middle frequency ranges, and low frequency ranges (e.g., any suitable frequency ranges, such as those of the LTE low band between 600 MHz and 1 GHZ, those less than 600 MHz, those greater than 1 GHZ, and so on). Moreover, the disclosed LNA 82 may withstand GSM blockers due to its high compression point, while maintaining low noise (e.g., a low noise figure). In particular, the LNA 82 may maintain noise at less than 1 dB, and noise at a 1 dB compression point (P_{1dB}) at less than 3 dB, with a GSM blocker present. Additionally, the LNA 82 may include a tunable IM3 cancelation circuit for coverage of the LTE low band.

As may be understood, process blocks shown in the schematic diagram of FIG. 6 may be part of a method for the processor 12 to operate of the LNA 82 (e.g., in the described operating modes 112, 114, 116, and/or an LNA 82 or device 10 protection mode as described in further detail below). In some embodiments, the method may be implemented by executing instructions stored in a tangible, non-transitory, computer-readable medium, such as the memory 14 or storage 16, using the processor 12. For example, the method may be performed at least in part by one or more software components, such as an operating system of the electronic device 10, one or more software applications of the electronic device 10, and the like. While the method is described using steps in a specific sequence, it should be understood that the present disclosure contemplates that the described steps may be performed in different sequences than the sequence illustrated, and certain described steps may be skipped or not performed altogether.

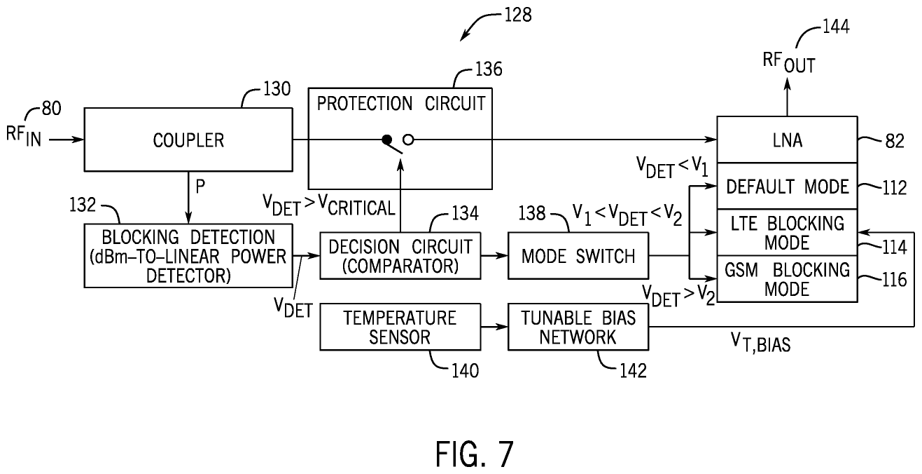

FIG. 7 is a block diagram of operating mode circuitry 128 including the LNA 82, according to embodiments of the present disclosure. In particular, the operating mode circuitry 128 includes circuitry coupled to the LNA 82, and may implement the operating modes shown in FIG. 6. The operating mode circuitry 128 may include a coupler 130 that receives an input radio frequency signal (e.g., the received signal 80 from the antennas 55, RFᵢₙ) and couples, determines, or extracts an amount of power P from the input signal 80. A blocking detection circuit 132 (e.g., a dBm-to-linear power detector) may receive the power P and determine an output voltage, V_{det}, based on the power P, that represents the power. That is, the output voltage. V_{det}, generated by the blocking detection circuit 132 has a direct (e.g., linear) relationship with the input power P. For example, the higher the power P, the higher the output voltage, V_{det}, and vice versa. A decision circuit 134 (e.g., a comparator) compares the output voltage, V_{det}, to a first or critical threshold voltage, V_{critical}. The critical threshold voltage may include a voltage that, if exceeded may shorten a lifetime of the LNA 82. As purely an example, V_{critical} may be 1 volt (V) or greater, 1.2 V or greater, 1.5 V or greater, 500 millivolts (mV) or greater, 500 mV or less, and so on, such as 1 V. If the V_{det} is greater than V_{critical}, then the processor 12 operates a protection circuit 136 to cause an open circuit, such that the input signal 80, having excessive power, may not reach the LNA 82, thus preventing shortening the lifetime of the LNA 82.

Otherwise, the decision circuit 134 compares the output voltage, V_{det}, to a second threshold V₁. If V_{det} is less than V₁, then V_{det} indicates that a blocker is not present, and the processor 12 operates a mode switch 138 to operate the LNA 82 in the first, default, high gain and/or power-saving mode 112. As purely an example, V₁ may be 400 mV or greater, 500 mV or greater, 800 mV or greater, 1 V or greater, 1.5 V or greater, 400 mV or less, and so on, such as 400 mV. It should be understood that the processor 12 may operate the LNA 82 in the first mode 112 for either LTE or GSM operation, and typically when a blocker is not present. If V_{det} is greater than V₁ but less than a third threshold V₂, then V_{det} indicates that a blocker is present for LTE operation, and the processor 12 operates the mode switch 138 to operate the LNA 82 in the second, high linearity, LTE blocking mode 114. As purely an example, V₂ may be 600 mV or greater, 800 mV or greater, 1 V or greater, 1.2 V or greater, 1.5 V or greater, 600 mV or less, and so on, such as 800 mV. If V_{det} is greater than the third threshold V₂ (and less than the first or critical threshold voltage, V critical), then V_{det} indicates that a blocker is present for GSM operation, and the processor 12 operates the mode switch 138 to operate the LNA 82 in the third, GSM blocking mode 116. This is because GSM has greater power in the 3GPP specification than LTE (e.g., at 0 dBm), so its corresponding threshold is greater than that of LTE. As indicated, V₁ is less than V₂, which is less than V_{det}.

Because IM3 reduction or cancelation may be sensitive to temperature changes or drift, the LNA 82 may be coupled to a temperature sensor 140 via a tunable bias network 142. The temperature sensor 140 may determine a temperature of the electronic device 10, the LNA 82, and/or an environment surrounding the electronic device 10 and/or the LNA 82, and the tunable bias network 142 may adjust components of the LNA 82 to compensate for any temperature changes (e.g., exceeding a threshold temperature difference) to ensure IM3 reduction or cancelation. For example, the tunable bias network 142 may include one or more switchable current sources that generate voltage (e.g., enabling setting analog voltages from digital signals). The LNA 82 may then output an amplified signal (RFₒᵤₜ) 144, which may be generated based on one of the three operating modes 112, 114, 116.

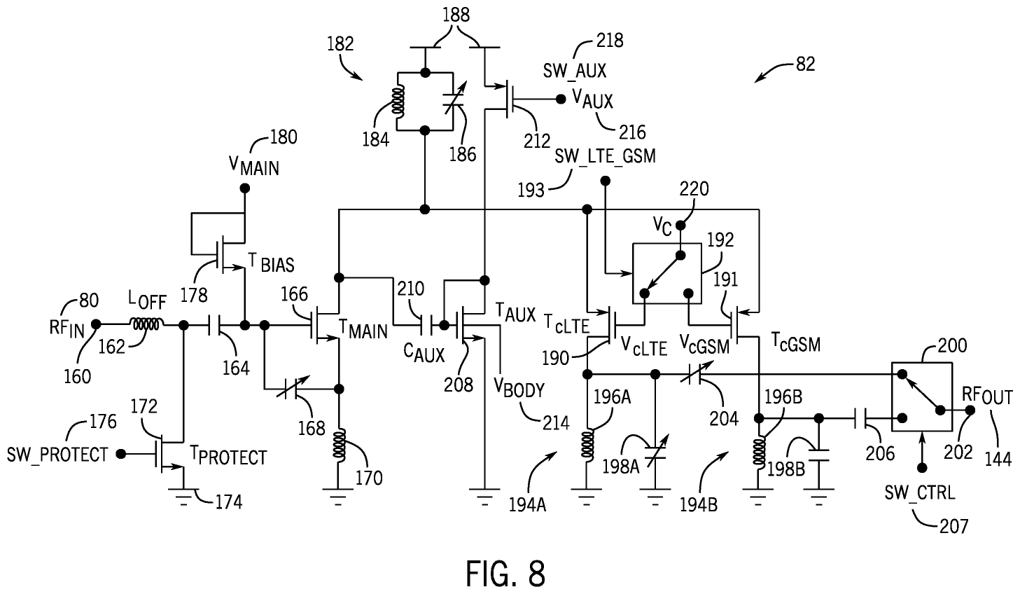

FIG. 8 is a circuit diagram of the LNA 82, according to embodiments of the present disclosure. As illustrated, the LNA 82 may include a folded cascode amplifier. The LNA 82 may receive the input received signal 80 (RFᵢₙ) at an input terminal 160, which may be coupled to an inductor (L_{off}) 162. The inductor 162 may be used for input matching by the LNA 82, and be disposed separate or off of an integrated circuit having the LNA 82. A direct current (DC) blocking capacitor 164 may be coupled to the inductor 162, which may reduce or prevent flow of DC. The DC block capacitor 164 may be coupled to a gate terminal of a main transistor (Tₘₐᵢₙ) 166, and a tunable capacitor 168 that may be coupled to the gate terminal and a source terminal of the main transistor 166. As illustrated, the main transistor 166 includes an n-channel metal-oxide-semiconductor (NMOS) transistor. The tunable capacitor 168 may include any suitable number or configuration of switches and capacitors that enable tunable matching. The tunable capacitor 168 and the source terminal of the main transistor 166 may also be coupled to an inductor 170 used for inductive degeneration.

The inductor 162 and the DC blocking capacitor 164 may be coupled to a protect transistor (T_{protect}) 172, which may be coupled to a ground 174. As illustrated, the protect transistor 172 may include an NMOS transistor. The protect transistor 172 may receive a protection signal (SW_PROTECT) 176 to activate the protect transistor 172 (e.g., when the output voltage, V_{det}, generated by the blocking detection circuit 132 is greater than the first or critical threshold voltage, V_{critical}), providing a short circuit to cause the received signal 80 to be directed to the ground 174 and away from other components of the LNA 82 (e.g., the main transistor 166). It should be understood that the protect transistor (T_{protect}) 172 may be part of the protection circuit 136 of FIG. 7, and, in some embodiments, may be part of the LNA 82, and in alternative or additional embodiments, be external to the LNA 82 but part of the operating mode circuitry 128 including the LNA 82.

The DC blocking capacitor 164, the main transistor 166, and the tunable capacitor 168 may also be coupled to a bias transistor (T_{bias}) 178, which may stabilize a bias point at high input voltage swings or high input powers and/or increase a compression point (P1_{dB}) (e.g., of the main transistor 166). As illustrated, the bias transistor 178 may include an NMOS transistor. The bias transistor 178 may be coupled to a main voltage source 180 (Vₘₐᵢₙ) via its gate terminal and drain terminal, and thus act as a bias metal-oxide-semiconductor field-effect transistor (MOSFET) diode. In particular, in some LNAs, a bias resistor may be included at the LNA input (e.g., the input terminal 160). The bias transistor 178 may replace such a resistor, and increase linearity (e.g., large signal linearity) of the LNA 82.

A drain terminal of the main transistor 166 may be coupled to an LC tank circuit 182, which may include an inductor 184 and a capacitor 186 (e.g., a tunable capacitor). The LC tank circuit 182 may be coupled to a voltage supply 188, and provide gain-peaking to increase gain of the LNA 82 and/or the compression point. The drain terminal of the main transistor 166 and the LC tank circuit 182 may be coupled to two cascode devices, including a source terminal of a cascode LTE transistor (T_{cLTE}) 190 and a source terminal of a cascode GSM transistor (T_{cGSM}) 191. As illustrated, the transistors 190, 191 are in a folded cascode topology that may reduce a Miller effect and increase voltage headroom. The folded cascode topology avoids having stacked transistors, enabling an increased or full voltage headroom and/or high compression point (P1_{dB}), resulting in higher input voltage swings before the illustrated circuit goes into compression. For example, in GSM operation, there may be high voltage swing due to a 0 dBm blocker and low positive supply voltage (VDD) (e.g., less than 2 volts (V), less than 1.5 V, less than 1.2 V, less than 1 V, and so on). Gain-peaking (e.g., as provided by the LC tank circuit 182) may further increase large signal linearity. As such, the folded cascode topology provides high gain and reverse isolation with a low noise figure.

A switch 192 coupled to gate terminals of the two transistors 190, 191 may enable switching between two operating modes (e.g., a first mode with the LTE transistor 190 activated, and a second mode with the GSM transistor 191 activated). The switch 192 may be activated by an LTE or GSM selection signal (SW_LTE_GSM) 193. The LTE transistor 190 may be activated when the LNA 82 operates in the first, default, high gain and/or power-saving mode 112 and/or the second, high linearity, LTE blocking mode 114, while the GSM transistor 191 may be activated when the LNA 82 operates in the third, GSM blocking mode 116. As illustrated, the LTE transistor 190 and the GSM transistor 191 may each include a p-channel metal-oxide-semiconductor (PMOS) transistor. Each drain terminal of the LTE transistor 190 and the GSM transistor 191 may be coupled to a respective LC tank circuit 194A, 194B (collectively 194), each including a respective inductor 196A, 196B (collectively 196) and a respective capacitor 198A, 198B (collective 198) (e.g., a tunable capacitor). The LC tank circuits 194 may set a frequency range for a received signal (e.g., 80) for their respective modes. Each drain terminal of the LTE transistor 190 and the GSM transistor 191 may also be coupled to an output switch 200 that outputs an output signal 144 (RFₒᵤₜ) at an output terminal 202 from either a path having the LTE transistor 190 (e.g., via the LC tank circuit 194A and a tunable capacitor 204 coupled to the LC tank circuit 194A) or a path having the GSM transistor 191 (e.g., via the LC tank circuit 194B and a capacitor 206 coupled to the LC tank circuit 194B). The output switch 200 may be controlled by an output control signal (SW_CTRL) 207.

The cascode LTE transistor 190 may be of a different size than the cascode GSM transistor 191. In particular, the cascode LTE transistor 190 may be smaller than (e.g., half a width of, a quarter of a width of, an eighth of a width of) the cascode GSM transistor 191 because the cascode GSM transistor 191 performs with higher linearity, resulting in a larger size and greater current consumption. A size of the inductor 196A coupled to the cascode LTE transistor 190, however, may be less than that of the inductor 196B coupled to the cascode GSM transistor 191. This may enable higher current consumption and a smaller load (e.g., of the inductor 196) to achieve a sufficient compression point.

The drain terminal of the main transistor 166 may also be coupled to a gate terminal and a drain terminal of an auxiliary transistor (Tₐᵤₓ) 208 via an auxiliary capacitor (Cₐᵤₓ) 210. The auxiliary transistor 208 may include an NMOS transistor, and decrease or cancel IM3 products of the LNA 82. The gate terminal and the drain terminal of the auxiliary transistor 208 may be coupled to a drain terminal of a transistor 212, which may include a PMOS transistor. The auxiliary transistor 208 may be supplied with a voltage V_{body} 214 (e.g., a bias voltage), and the transistor 212 may be supplied with a voltage Vₐᵤₓ 216 (e.g., a bias voltage). The processor 12 may tune or adjust IM3 cancelation by adjusting V_{body} 214 and Vₐᵤₓ 216 (e.g., via an auxiliary signal (SW_AUX) 218). Such may be the case when receiving a signal 80 of a different frequency band, and the processor 12 retunes the auxiliary transistor 208 and/or the transistor 212 for different IM3 cancelation (e.g., of a different frequency). Additionally or alternatively, the tunable bias network 142 may include one or more switchable current sources that adjust V_{body} 214 and Vₐᵤₓ 216 to tune or adjust IM3 cancelation based on changes in temperature, as determined by the temperature sensor 140. A voltage, V_{c}, 220 (e.g., a bias voltage) may be directed by the switch 192 to bias the LTE transistor 190 or the GSM transistor 191.

While the transistors and switches described in FIG. 8 are illustrated with certain implementations (e.g., PMOS or NMOS transistors), in additional or alternative embodiments, any suitable switching circuitry may be used for the illustrated transistors and switches.

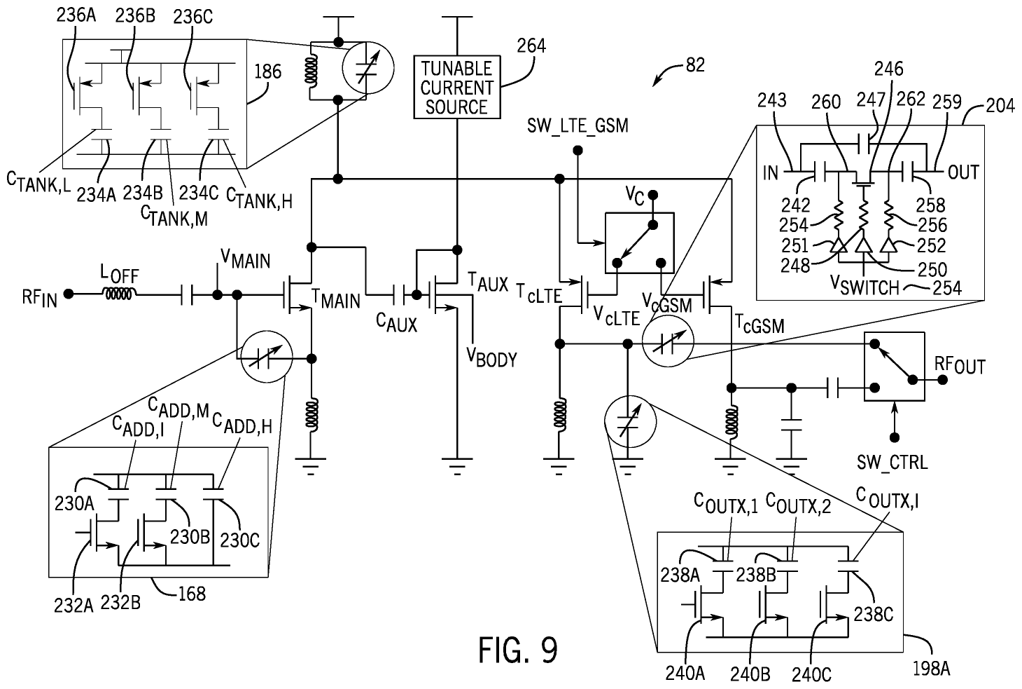

FIG. 9 is a circuit diagram of the LNA 82 showing components of the tunable capacitors 168, 186, 198A, 204, according to embodiments of the present disclosure. The tunable capacitor 168 may include a set of capacitors 230A (C_{add,1}), 230B (C_{add,m}), 230C (C_{add,h}) (collectively 230) that correspond to different frequency bands (e.g., a low frequency band, a middle frequency band, and a high frequency band, respectively). The capacitor 230A corresponding to the low frequency band and the capacitor 230B corresponding to the middle frequency band may each be added or removed from the tunable capacitor circuit 168 via coupled switching circuitries or transistors 232A, 232B (collectively 232), respectively. As illustrated, the transistors 232 may include NMOS transistors.

Similarly, the tunable capacitor 186 may include a set of capacitors 234A (C_{tank,1}), 234B (C_{tank,m}), 234C (C_{tank,h}) (collectively 234) that correspond to different frequency bands (e.g., a low frequency band, a middle frequency band, and a high frequency band, respectively). The capacitors 234 may each be added or removed from the tunable capacitor circuit 186 via coupled switching circuitries or transistors 236A, 236B, 236C (collectively 236), respectively. As illustrated, the transistors 236 may include PMOS transistors.

The tunable capacitor 198A may include a set of capacitors 238A (C_{outx,1}), 238B (C_{outx,2}), 238C (C_{outx,i}) (collectively 238) that correspond to different operating modes of the LNA 82. The capacitors 234 may each be added or removed from the tunable capacitor circuit 198A via coupled switching circuitries or transistors 240A, 240B, 240C (collectively 240), respectively. As illustrated, the transistors 240 may include NMOS transistors.

The tunable capacitor 204 may include a first capacitor 242 coupled to an input terminal 243, a first resistor 244, a drain terminal of a transistor 246, and a second capacitor 247. A gate of the transistor 246 may be coupled to a second resistor 248, which may be coupled to an output terminal of an inverter 250. The first resistor 244 may also be coupled to an output terminal of a first amplifier 251, which has an input terminal coupled to an input terminal of the inverter 250, and an input terminal of a second amplifier 252, and a switching voltage 254 (V_{switch}). An output terminal of the second amplifier 252 may be coupled to a third resistor 256, which may be coupled to a source terminal of the transistor 246 and a third capacitor 258. The third capacitor 258 may be coupled to the second capacitor 247 and an output terminal 259 of the tunable capacitor 204.

For each tunable capacitor 168, 186, 198A, 204, switching the available capacitors in and out of the respective tunable capacitor circuits 168, 186, 198A, 204 may enable matching of different frequency bands and/or operating modes. For example, for the tunable capacitor 168, switching more capacitors 234 into the tunable capacitor circuit 168 increases capacitance of the tunable capacitor 168, causing the LNA 82 to match lower frequencies, while switching less capacitors 234 into the tunable capacitor circuit 168 decreases the capacitance of the tunable capacitor 168, causing the LNA 82 to match higher frequencies.

It should be noted that while the tunable capacitors 168, 186, 198A may be switched to a fixed potential (e.g., ground or a negative supply voltage, VDD), the tunable capacitor 204 is in series, and may be used for field-effect transistor (FET) biasing. In particular, nodes 260, 262 may be set to a fixed potential to switch the tunable capacitor 204 off or on. FIG. 9 also includes a tunable current source 264 in place of the transistor 212 from FIG. 8, as the transistor 212, in operation, operates as a tunable current source. The tunable current source 264 may generate or adjust analog voltages (e.g., V_{body} 214, Vₐᵤₓ 216) to tune or adjust IM3 cancelation based on, for example, changes in temperature, as determined by the temperature sensor 140.

It should be understood that, even though the tunable capacitors 168, 186, 198A, 204 are each illustrated to include a certain number and configuration of components, more or less components or different configurations are contemplated. For example, the tunable capacitors 168, 186, 198A may each include more or less branches of capacitors and switching circuitries or transistors. Moreover, while the transistors and switches described in FIG. 9 are illustrated with certain implementations (e.g., PMOS or NMOS transistors), in additional or alternative embodiments, any suitable switching circuitry may be used for the illustrated transistors and switches.

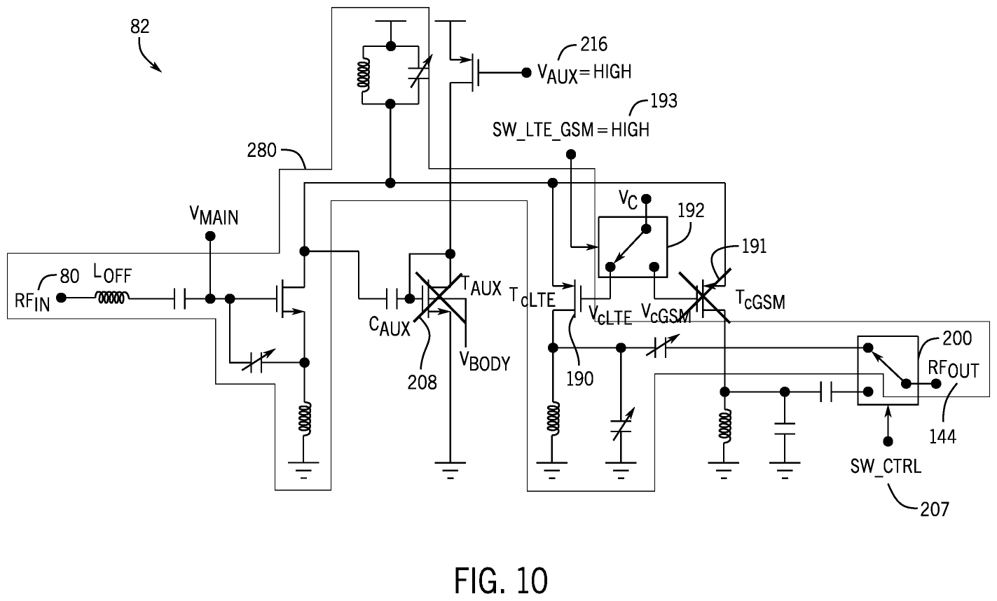

FIG. 10 is the circuit diagram of the LNA 82 of FIG. 8 when operating in the first, default, high gain and/or power-saving mode 112, according to embodiments of the present disclosure. As noted above, the processor 12 may operate the LNA 82 in the mode 112 when the determined voltage, V_{det}, of the received signal 80, as determined by the blocking detection circuit 132, is less than the threshold voltage V₁ (indicating that a blocker is not present). A path 280 that the input received signal 80 follows when the first mode 112 is selected is indicated via shading. As indicated by being crossed out, the auxiliary transistor (Tₐᵤₓ) 208 and the GSM transistor (T_{cGSM}) 191 are deactivated or switched off. In particular, the processor 12 may set the voltage Vₐᵤₓ 216 to 0 V or a high value (e.g., 1.2 V or any other suitable voltage that represents the high value) to deactivate the auxiliary transistor 208. Similarly, the processor 12 may set the LTE or GSM selection signal (SW_LTE_GSM) 193 to a value corresponding to LTE operation (e.g., a high value) to cause the switch 192 to select the LTE transistor (T_{cLTE}) 190, such that the path 280 includes the LTE transistor 190 and not the GSM transistor 191, thus deactivating the GSM transistor 191. The processor 12 may also set the output control signal (SW_CTRL) 207 to a value corresponding to LTE operation (e.g., a high value) to cause the switch 200 to select the LTE transistor 190, such that the path 280 includes the LTE transistor 190 and not the GSM transistor 191, thus outputting the output signal (RFₒᵤₜ) 144 based on activating the LTE transistor 190.

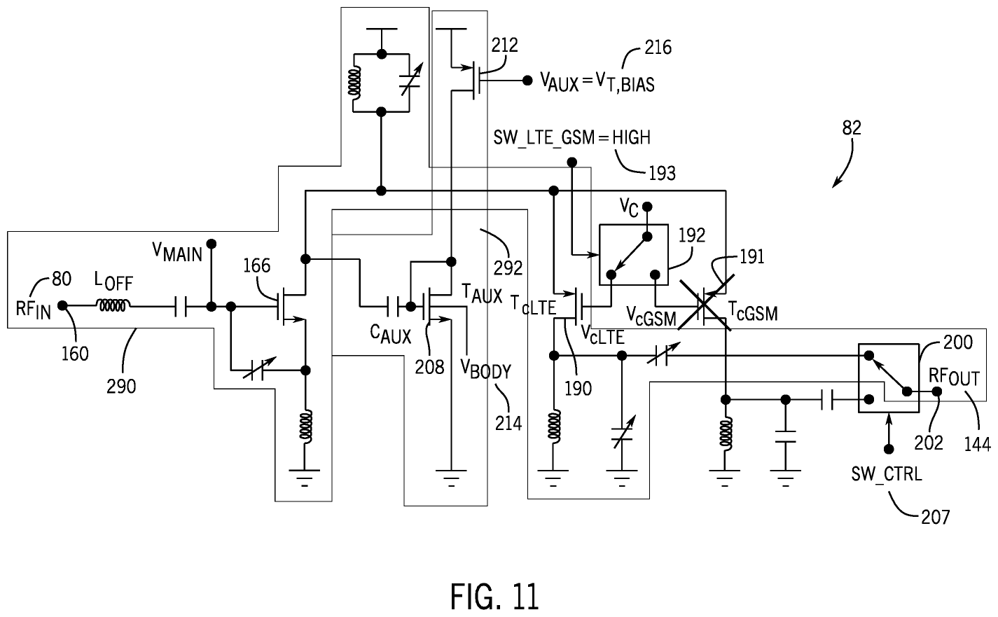

FIG. 11 is the circuit diagram of the LNA 82 of FIG. 8 when operating in the second, high linearity, LTE blocking mode 114, according to embodiments of the present disclosure. As noted above, the processor 12 may operate the LNA 82 in the mode 114 when the determined voltage, V_{det}, of the received signal 80, as determined by the blocking detection circuit 132, is greater than the threshold voltage V₁ but less than the threshold voltage V₂ (indicating that a blocker is present for LTE operation). As indicated by being crossed out, the GSM transistor (T_{cGSM}) 191 is deactivated or switched off. In particular, the processor 12 may set the LTE or GSM selection signal (SW_LTE_GSM) 193 to a value corresponding to LTE operation (e.g., a high value) to cause the switch 192 to select the LTE transistor (T_{cLTE}) 190, such that the path 290 includes the LTE transistor 190 and not the GSM transistor 191, thus deactivating the GSM transistor 191.

The path 290 may include an auxiliary path 292, and the processor 12 may tune or adjust voltages in the auxiliary path 292 (e.g., V_{body} 214, Vₐᵤₓ 216) to reduce distortion and/or increase performance of the LNA 82. For example, the processor 12 may set the auxiliary voltage Vₐᵤₓ 216 to a threshold bias voltage (V_{t,bias}), such as a minimum gate-to-source voltage (V_{GS}) that creates a conducting path between source and drain terminals of the transistor 212. The auxiliary path 292, including the auxiliary transistors 208, 212, may enable reduction or cancelation of IM3 products when operating in the second, high linearity mode 114. In particular, the processor 12 may adjust or tune the IM3 cancelation by adjusting or tuning the bias voltages Vₘₐᵢₙ 180, V_{c} 220, Vₐᵤₓ 216, and/or V_{body} 214. It should be noted that the higher the achieved out-of-band IIP3, the more sensitive the IM3 cancelation circuitry may be to process, variation, and/or temperature (PVT) changes. Accordingly, the LNA 82 may be calibrated (e.g., at a manufacturing facility or factory) and/or use temperature sensing and tuning (e.g., via the temperature sensor 140 and/or the tunable bias network 142) to compensate for temperature changes by, for example, retuning at least some of the bias voltages (e.g., to ensure that the corresponding transistors, such as the main transistor 166, the LTE transistor 190, the GSM transistor 191, and so on, are in saturation). For example, the processor 12 may adjust or tune V_{body} 214 to ensure that the auxiliary transistor 208 remains in a saturation region, which may decrease sensitivity of the auxiliary transistor 208 to PVT changes. In practice, settings of the LNA 82 may be determined at the manufacturing facility that enable the LNA 82 to operate with high or peak performance for different frequencies of received signals 80 and/or at different temperatures, and the settings may be stored in a data structure, such as the memory 14 or the storage 16, in, for example, a lookup table. In operation, as the LNA 82 receives signals 80 at the different frequency and/or at different temperatures, the settings may be retrieved from the data structure and be implemented at the LNA 82 by, for example, the processor 12. It should be understood that the switches 192 and 200 may also include transistors that may operate in a saturation region. While, in some embodiments, the transistors (including the main transistor 166, the LTE transistor 190, the GSM transistor 191, the auxiliary transistors 208, 212, the switches 192, 200, and so on) may be operated in a sub-threshold, non-saturation, doing so may cause the transistors to be more susceptible to changes in PVT.

Moreover, the auxiliary path 292 may enable the processor 12 to perform tunable post-distortion techniques to reduce or cancel nonlinearities of the main transistor 166 via the auxiliary transistors 208, 212. Output current (iₒᵤₜ) from the auxiliary path 292 may be expressed by Equation 3 below, where iₘₐᵢₙ represents output current from the main transistor 166, and iₐᵤₓ represents output current from the auxiliary transistor 208:

$${i}_{o u t} = {i}_{m a i n} + {i}_{a u x} \qquad ( Equation 3 )$$

iₘₐᵢₙ may be expressed by Equation 4 below, where g is an amplification factor, and v is voltage:

$${i}_{m a i n} = {g}_{1} {v}_{1} + {g}_{2} {v}_{2} + {g}_{3} {v}_{3} = {g}_{1} {v}_{1} + {f}_{n 1} ( {v}_{1} ) \qquad ( Equation 4 )$$

fₙ₁(v₁) may represent nonlinearities in the main transistor 166. Iₐᵤₓ may be expressed by Equation 5 below:

$${i}_{a u x} = - {f}_{n 1} ( {v}_{1} ) \qquad ( Equation 5 )$$

Accordingly, the output current (iₒᵤₜ) from the auxiliary path 292 may be given as shown in Equation 6 below, canceling out the nonlinearities (fₙ₁(v₁)) of the main transistor 166:

$${i}_{o u t} = {g}_{1} {v}_{1} \qquad ( Equation 6 )$$

Using the auxiliary path 292 in this manner (e.g., by disposing the auxiliary transistor 208 downstream from the main transistor 166) may also reduce the noise figure and improve input matching (e.g., matching impedance at the output terminal 202 to the input terminal 160, such as matching the output impedance to an input impedance of 50 ohms, for example). While the LNA 82 uses the auxiliary path 292 to perform tunable post-distortion techniques, it should be understood that other techniques are contemplated to reduce or cancel the nonlinearities of the main transistor 166.

The processor 12 may also set the output control signal (SW_CTRL) 207 to a value corresponding to LTE operation (e.g., a high value) to cause the switch 200 to select the LTE transistor 190, such that the path 290 includes the LTE transistor 190 and not the GSM transistor 191, thus outputting the output signal (RFₒᵤₜ) 144 based on activating the LTE transistor 190.

As shown, the auxiliary transistor 208 is configured as an adaptively biased diode connected FET with forward body bias due to coupling its drain and gate terminals. This may enable the auxiliary transistor 208 to be tunable and reduce or cancel intermodulation (IMD) products, acting as an IMD sink. In additional or alternative embodiments, the auxiliary transistor 208 may be provided in other configurations to act as an IMD sink (e.g., with common source, as a PMOS common gate device, and so on). Forward-body biasing the auxiliary transistor 208 may ensure FET operation in a saturation region of the auxiliary transistor 208 to decrease sensitivity to parasitic capacitances.

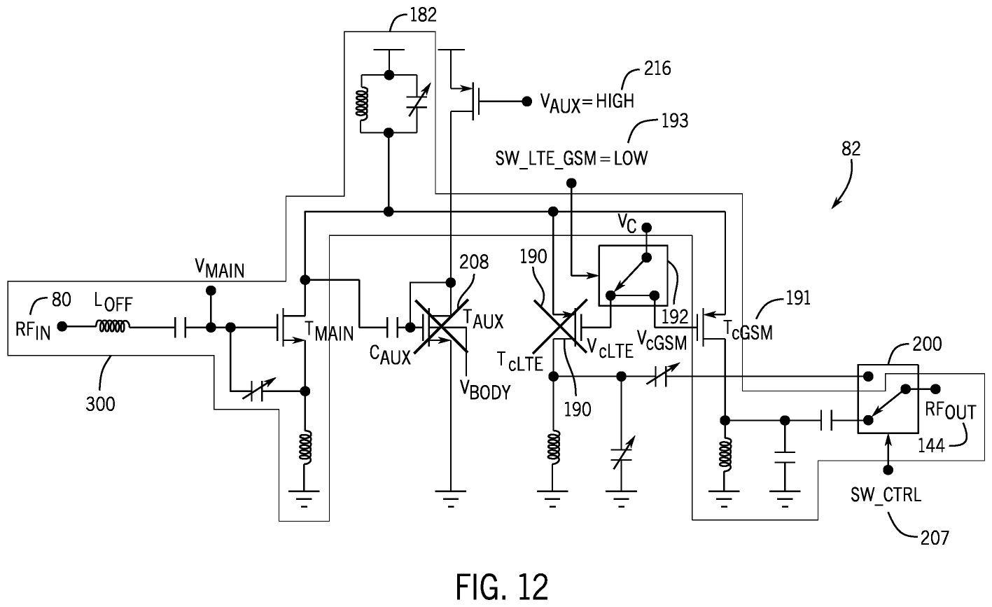

FIG. 12 is the circuit diagram of the LNA 82 of FIG. 8 when operating in the third, GSM-blocking mode 116, according to embodiments of the present disclosure. As noted above, the processor 12 may operate the LNA 82 in the mode 116 when the determined voltage, V_{det}, of the received signal 80, as determined by the blocking detection circuit 132, is greater than the threshold voltage V₂ and less than the critical threshold voltage, V_{critical} (indicating that a blocker is present for GSM operation). A path 300 that the input received signal 80 follows when the third mode 116 is selected is indicated via shading. As indicated by being crossed out, the auxiliary transistor (Tₐᵤₓ) 208 and the LTE transistor (T_{cLTE}) 190 are deactivated or switched off. In particular, the processor 12 may set the voltage Vₐᵤₓ 216 to 0 V or a high value (e.g., 1.2 V or any other suitable voltage that represents the high value) to deactivate the auxiliary transistor 208. Similarly, the processor 12 may set the signal LTE or GSM selection signal (SW_LTE_GSM) 193 to a value corresponding to GSM operation (e.g., a low value) to cause the switch 192 to select the GSM transistor (T_{cGSM}) 191, such that the path 300 includes the GSM transistor 191 and not the LTE transistor 190, thus deactivating the LTE transistor 190. Additionally, the LC tank circuit 182 may perform filtering and/or gain-peaking operations during the third mode 116. The processor 12 may also set the output control signal (SW_CTRL) 207 to a value corresponding to GSM operation (e.g., a low value) to cause the switch 200 to select the GSM transistor 191, such that the path 300 includes the GSM transistor 191 and not the LTE transistor 190, thus outputting the output signal (RFₒᵤₜ) 144 based on activating the GSM transistor 191.

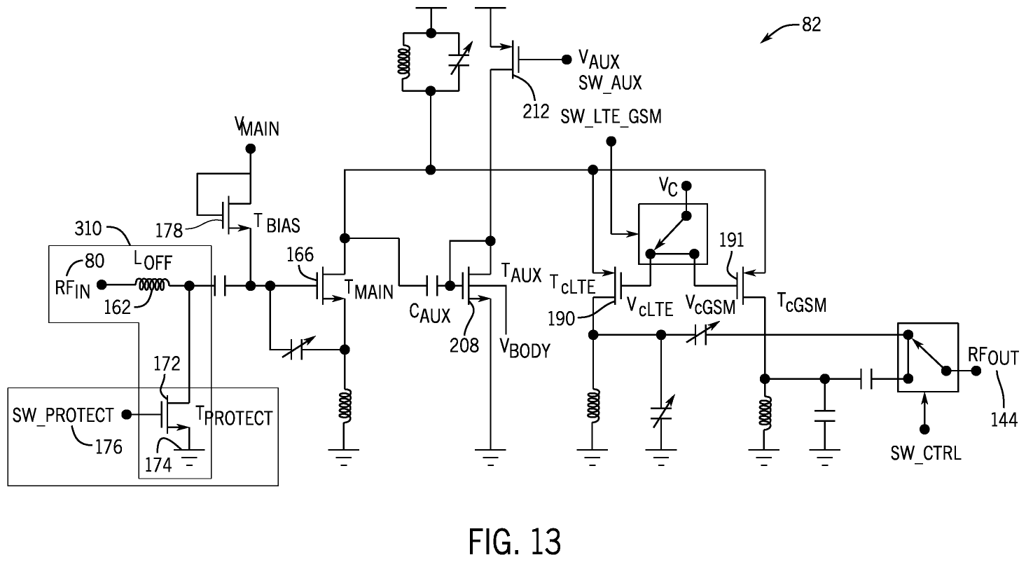

FIG. 13 is the circuit diagram of the LNA 82 of FIG. 8 when operating in an LNA or device protection mode, according to embodiments of the present disclosure. As noted above, the processor 12 may operate the LNA 82 in the protection mode when the determined voltage, V_{det}, of the received signal 80, as determined by the blocking detection circuit 132, is greater than the critical threshold voltage, V_{critical} (indicating that it may shorten a lifetime of the LNA 82). A path 310 that the input received signal 80 follows when the protection mode is selected is indicated via shading. In particular, the processor 12 may set the protection signal (SW_PROTECT) 176 to a value corresponding to protecting the LNA 82 or electronic device 10 (e.g., a high value) to activate or switch on the auxiliary transistor 208. This may cause the received signal 80 to traverse to the ground 174, thus avoiding traversing to the LNA 82 (or at least the main transistor 166, the auxiliary transistor 208, the transistor 212, the bias transistor 178, the LTE transistor 190, and the GSM transistor 191), thus protecting the LNA 82 and increasing its lifetime. It should be understood that when the LNA 82 is operating in the first power-saving mode 112, the second LTE blocking mode 114, and/or the third GSM blocking mode 116, the protect transistor (T_{protect}) 172 may be deactivated or switched off such that the input received signal 80 does not traverse to the ground 174.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

1. An amplifier comprising:
a first transistor;
an inductor and a capacitor coupled in parallel and coupled to a terminal of the first transistor;
a second transistor coupled to the terminal of the first transistor, the inductor, and the capacitor;
a third transistor coupled to the terminal of the first transistor, the inductor, and the capacitor; and
switching circuitry coupled to the second transistor and the third transistor.

2. The amplifier of claim 1, wherein the first transistor comprises an n-channel metal-oxide-semiconductor, and the terminal comprises a source terminal.

3. The amplifier of claim 1, wherein the first transistor comprises a second terminal coupled to an input terminal of the amplifier.

4. The amplifier of claim 3, wherein the second terminal is coupled to second switching circuitry configured to send a signal received at the input terminal to ground when activated.

5. The amplifier of claim 1, wherein the second transistor comprises a second terminal, and the third transistor comprises a third terminal, the second terminal and the third terminal being coupled to the first transistor, the inductor, and the capacitor.

6. The amplifier of claim 5, wherein the second transistor comprises a fourth terminal, and the third transistor comprises a fifth terminal, the fourth terminal and the fifth terminal being coupled to an output terminal of the amplifier.

7. An electronic device comprising:
an amplifier configured to operate in a plurality of modes;
a blocker detection circuit coupled to the amplifier configured to detect a presence of a blocking signal; and
a switch coupled to the amplifier and configured to select a mode of the plurality of modes based on the presence of the blocking signal.

8. The electronic device of claim 7, comprising a protection circuit coupled to the amplifier and configured to protect the amplifier from excessive voltage by sending a received signal to ground.

9. The electronic device of claim 7, comprising a temperature sensor configured to detect a temperature of the amplifier or the electronic device.

10. The electronic device of claim 9, comprising a tunable bias network coupled to the temperature sensor and the amplifier, the tunable bias network configured to adjust the amplifier based on the temperature.

11. The electronic device of claim 7, comprising a coupler configured to receive an input signal and couple an amount of power from the input signal.

12. The electronic device of claim 11, wherein the blocker detection circuit is configured to determine a voltage based on the amount of power.

13. The electronic device of claim 12, comprising a decision circuit coupled to the blocker detection circuit and the switch, the decision circuit configured to perform a comparison of the voltage to a plurality of threshold voltages.

14. The electronic device of claim 13, wherein the plurality of threshold voltages is associated with the plurality of modes, and the switch is configured to select the mode based on the comparison.

15. A method comprising:
operating, via processing circuitry, an amplifier in a first mode based on a voltage of a received signal being greater than a threshold voltage, the first mode configured to protect the amplifier from the voltage;
operating, via the processing circuitry, the amplifier in a second mode based on a signal blocker not being present;
operating, via the processing circuitry, the amplifier in a third mode based on the signal blocker being present and the received signal corresponding to a first radio access technology; and
operating, via the processing circuitry, the amplifier in a fourth mode based on the signal blocker being present and the received signal corresponding to a second radio access technology.

16. The method of claim 15, wherein operating, via the processing circuitry, the amplifier in the first mode comprises sending the received signal to ground.

17. The method of claim 15, wherein operating, via the processing circuitry, the amplifier in the second mode comprises consuming lower current and achieving higher gain than operating, via the processing circuitry, the amplifier in the third mode or the fourth mode.

18. The method of claim 15, wherein operating, via the processing circuitry, the amplifier in the third mode or the fourth mode comprises achieving higher linear performance than operating, via the processing circuitry, the amplifier in the second mode.

19. The method of claim 15, wherein the first radio access technology comprises Long Term Evolution (LTE) and the second radio access technology comprises Global System for Mobile (GSM).

20. The method of claim 15, wherein the received signal comprises a frequency between 600 megahertz and 1 gigahertz.
